(19) United States
(12) Patent Application Publication
(10) Pub. No.: US 2009/0280418 A1
(43) Pub. Date: Nov. 12, 2009

(54) EXPOSURE APPARATUS, CORRECTION METHOD, AND DEVICE MANUFACTURING METHOD

(75) Inventor: Hideki Matsuda, Kawachi-gun (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/463,235

(22) Filed: May 8, 2009

(30) Foreign Application Priority Data
May 12, 2008 (JP) 2008-124968

(51) Int. Cl. G03F 7/20; G03B 27/42; G03B 27/32

(52) U.S. Cl. 430/30; 355/53; 355/77

(57) ABSTRACT

An exposure apparatus comprising a projection optical system configured to project a pattern of an original onto a substrate; and a control unit, wherein the control unit acquires a result of measuring a line width of an image of a first mark and a position of an image of a second mark, wherein the first mark and the second mark are formed on the substrate at each position while gradually changing a position of a substrate stage in an optical-axis direction, and derives a position shift amount of the image of the second mark formed on the substrate held by the substrate stage at a position, in the optical-axis direction, at which an extremum of a change of line width of the image of the first mark is measured.

### BACKGROUND OF THE INVENTION

1. Field of the Invention

The present invention relates to a technique of measuring, using various kinds of aberration measurement methods, the optical characteristics, such as the wavefront aberration and the focus position in the optical-axis direction, of a projection optical system in an exposure apparatus used in manufacturing, for example, a semiconductor device, a liquid crystal display device, and a thin film magnetic head by lithography.

2. Description of the Related Art

U.S. Pat. Nos. 5,828,455 and 5,978,085 propose a method of measuring the wavefront aberration of a projection optical system (to be referred to as the ISI method hereinafter). There is another measurement method of obliquely illuminating special diffraction grating marks by approaches proposed in Japanese Patent Laid-Open Nos. 2003-178968 and 2003-318090, and calculating the Zernike coefficient based on position shifts of images of the marks (to be referred to as the ZEX method hereinafter). There is still another measurement method of forming a pinhole on the surface, opposite to the pattern surface, of a pattern transfer mask (to be simply referred to as a mask hereinafter), as proposed in the pamphlet of International Publication WO 03/088329, obliquely illuminating special diffraction grating marks, measuring position shifts of images of the marks at a plurality of points, and calculating the wavefront aberration (to be referred to as the SPIN method hereinafter).

In the above-mentioned ISI, ZEX, and SPIN methods and the like, a large number of marks for measuring aberration to measure position shifts are generally formed by transferring on a photosensitive material (to be referred to as a resist hereinafter) on a substrate (to be referred to as a wafer hereinafter). Position shifts of images of these marks (to be often simply referred to as marks hereinafter) are measured using, e.g., an overlay measurement device, and the obtained measurement values are arithmetically processed, thereby calculating, e.g., the Zernike coefficient.

A pinhole or an opening with a special shape is formed in a mask for transferring such marks. When the marks are illuminated using the pinhole or the opening, most of them are illuminated with an angular distribution asymmetrical with respect to the optical-axis direction of the projection optical system (to be referred to as oblique incidence hereinafter). As a consequence, the marks transferred on the resist have oblique sectional shapes. When marks for measuring aberration, which include the marks having oblique sectional shapes, are measured using an overlay measurement device, measurement errors often occur. The mechanism of occurrence of measurement errors will be explained by taking the SPIN or ISI method as an example.

In the SPIN or ISI method, a mark group Pw (see FIG. 12A) is transferred on a resist by oblique illumination via a pinhole in a mask, as shown in FIG. 11. In addition, a reference mark group Rw (see FIG. 12B) different from the mark group Pw is transferred so as to be superimposed on the mark group Pw by non-oblique illumination. Relative position shifts of individual superimposed marks Bw in a unit Sw of marks for measuring aberration are measured by, e.g., an overlay measurement device, and the obtained measurement values are arithmetically processed, thereby calculating the wavefront aberration.

The overlay measurement device generally observes the mark from directly above the wafer surface by a scope, and a measurement value is output using the measured wavefront information obtained by the observation, as shown in FIG. 13A. For example, if the measured waveforms in marks Bw1 and Bw2 of the mark Bw are asymmetrical, as shown in FIG. 13B, measurement errors occur in the measurement values of the marks Bw1 and Bw2 in a direction V upon the measurement using, e.g., the overlay measurement device.

In the SPIN or ISI method, the oblique incident angle on each mark in the mark group Pw shown in FIG. 12A changes along its radial direction. For example, the oblique incident angle on each mark existing in the direction of a radius R in FIG. 12A increases in the direction in which the radius increases, i.e., marks which sample portions closer to the pupil of the projection optical system receive light at larger oblique incident angles, as shown in FIG. 14. The tilt angle of each mark section in the resist increases along with the increase in the oblique incident angle. The tilt direction is symmetrical with respect to the pupil center. Therefore, the measured waveforms in, for example, the marks Bw1 and Bw2 of the mark Bw in the mark group Sw shown in FIG. 12C are asymmetrical, generating measurement errors in the measurement values in the direction V.

In the SPIN or ISI method, the oblique incident angle gradually increases along the direction in which the radius increases, so the measurement error amount also gradually changes. When this error amount is converted into a Zernike coefficient, it turns into an error in a spherical aberration term. The error in a spherical aberration term will be explained in more detail herein. Because the measurement error amount has an almost magnification-dependent distribution with respect to the pupil center, the result of arithmetically processing all measurement values including the error amount includes errors of the Zernike coefficients in low-order spherical aberration terms describing focus components. This is because the derivative wavefronts of low-order spherical aberration terms describing focus components are magnification components with respect to the pupil center. The low-order spherical aberration terms describe focus components, whereas the Zernike coefficients in other high-order spherical aberration terms have a given sensitivity to the focus component, i.e., the low-order spherical aberration terms corresponding to the NA of the projection optical system and the light source wavelength. Accordingly, to calculate the Zernike coefficients in all spherical aberration terms and compare the calculated values with other Zernike coefficients in the projection optical system, the Zernike coefficient needs to be a value at a focus position serving as a reference. For example, the Zernike coefficients in high-order spherical aberration terms are calculated and corrected so that they have values at the position of zero focus. At this time, the Zernike coefficient is calculated and corrected in accordance with a focus value, which itself is influenced by the above-mentioned measurement errors. As a consequence, the high-order spherical aberration terms are also influenced by errors corresponding to the measurement errors.

The marks Bw1 and Bw2 themselves have oblique sectional shapes, so measured waveforms having asymmetrical two ends, for example, as shown in FIG. 15, are obtained using these marks. Therefore, the same problem is posed even when, for example, a relative position shift of the mark Bw1 is solely measured. The magnitude of the measurement error changes depending on the oblique incident angle, the type of resist, the resist film thickness, the type of measurement device, and the measurement algorithm. Measurement errors may occur not only when the mark is transferred on the resist but also when a latent image of the mark is measured.

In the SPIN or ISI method, certain marks in the mark group Sw, for example, a pair of marks in the measurement direction, such as marks Dw1 and Dw2, in a mark Dw shown in FIG. 16 often have different line widths. In this case, the difference in line width may worsen the measurement errors in cooperation with mark asymmetry attributed to oblique illumination.

In recent years, aberration measurement methods such as the SPIN, ISI, and ZEX methods are widely used in measuring the aberration of a projection optical system mounted on the main body of an exposure apparatus, and serve to guarantee the performance of the projection optical system in many cases. The guaranteed performance standards have become stricter year after year to the degree that errors attributed to the above-mentioned measurement errors are non-negligible.

### SUMMARY OF THE INVENTION

The present invention provides a technique of improving the absolute value precision of a measurement method by eliminating any errors attributed to, e.g., the oblique incident angle, the type of resist, the resist film thickness, the type of measurement device, and the measurement algorithm.

According to the first aspect of the present invention, there is provided an exposure apparatus comprising: a projection optical system configured to project a pattern of an original onto a substrate; and a control unit, wherein the control unit acquires a result of measuring a line width of an image of a first mark and a position of an image of a second mark, wherein the first mark and the second mark are formed on the substrate at each position while gradually changing a position of a substrate stage in an optical-axis direction, and derives a position shift amount of the image of the second mark formed on the substrate held by the substrate stage at a position, in the optical-axis direction, at which an extremum of a change of line width of the image of the first mark is measured.

According to the second aspect of the present invention, there is provided a correction method of correcting aberration of a projection optical system in accordance with a measurement result of an image of a mark for measuring aberration, the method comprises: measuring a line width of an image of a first mark and a position of an image of a second mark, wherein the first mark and the second mark are formed on a substrate at each position while gradually changing a position of a substrate stage in an optical-axis direction; deriving a position shift amount of the image of the second mark formed on the substrate held by the substrate stage at a position, in the optical-axis direction, at which an extremum of a change of line width of the image of the first mark is measured; and correcting aberration of the projection optical system by correcting, using the derived position shift amount, the measurement result of the image of the mark for measuring aberration.

According to the third aspect of the present invention, there is provided a device manufacturing method comprising: exposing a substrate by an exposure apparatus; and developing the substrate, wherein the exposure apparatus includes a projection optical system configured to project a pattern of an original onto a substrate, and a control unit, and the control unit acquires a result of measuring a line width of an image of a first mark and a position of an image of a second mark, wherein the first mark and the second mark are formed on the substrate at each position while gradually changing a position of a substrate stage in an optical-axis direction, and derives a position shift amount of the image of the second mark formed on the substrate held by the substrate stage at a position, in the optical-axis direction, at which an extremum of a change of line width of the image of the first mark is measured.

Further features of the present invention will become apparent from the following description of exemplary embodiments with reference to the attached drawings.

### BRIEF DESCRIPTION OF THE DRAWINGS

FIG. 1 is a view illustrating an example of the arrangement of an exposure apparatus 10 according to one embodiment of the present invention;

FIG. 2 is a view schematically illustrating an example of the formation of a calibration mark unit according to the first embodiment on a wafer;

FIGS. 3A to 3C are views schematically illustrating an example of the calibration mark unit;

FIG. 4 is a view illustrating an example of the structures of marks Ms and Mc shown in FIGS. 3B and 3C;

FIG. 5 is a view for explaining an example of a method of measuring a change of line width of the mark Mc;

FIG. 6 is a flowchart illustrating an example of the sequence of the operation of the exposure apparatus 10 shown in FIG. 1;

FIG. 7A is a graph illustrating an example of the measurement result of the mark Ms shown in FIGS. 3B and 3C;

FIG. 7B is a graph illustrating an example of the measurement result of the mark Mc shown in FIGS. 3B and 3C;

FIG. 8 is a view illustrating an example of the relationship between marks and an opening according to the second embodiment;

FIG. 9 is a view schematically illustrating an example of the formation of a calibration mark unit according to the second embodiment on a wafer;

FIG. 10 is a view schematically illustrating an example of the calibration mark unit according to the second embodiment;

FIG. 11 is a view schematically illustrating an example of the formation of marks for measuring aberration on a wafer;

FIGS. 12A to 12C are views schematically illustrating an example of a mark group;

FIGS. 13A and 13B are views schematically illustrating an example of the measured waveforms obtained by measuring marks;

FIG. 14 is a graph illustrating an example of the relationship between the direction of a radius R and the oblique incident angle in a mark group;

FIG. 15 is a view schematically illustrating an example of the measured waveform obtained by measuring a mark having a section formed into an oblique shape by oblique illumination; and

FIG. 16 is a view for explaining changes of line width of marks.

### DESCRIPTION OF THE EMBODIMENTS

Preferred embodiments of the present invention will now be described in detail with reference to the drawings. It should be noted that the relative arrangement of the components, the numerical expressions and numerical values set forth in these embodiments do not limit the scope of the present invention unless it is specifically stated otherwise.

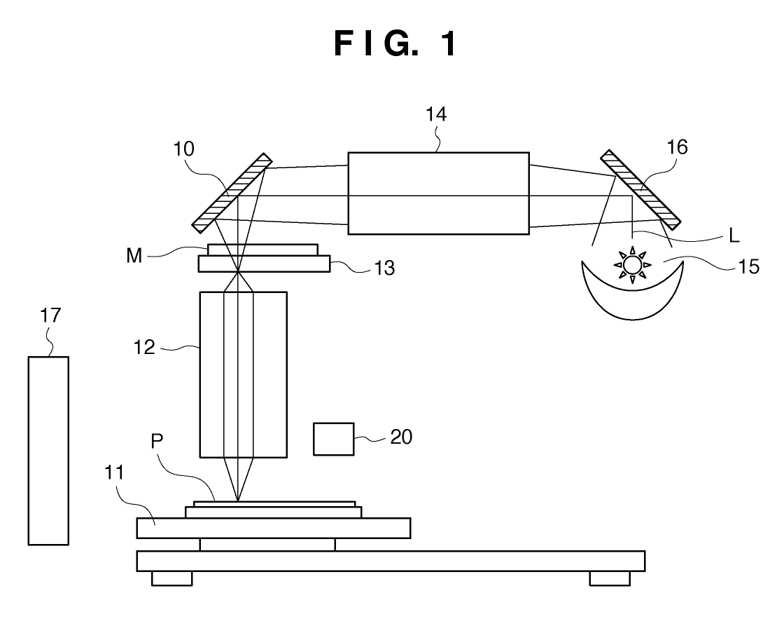

An example of the arrangement of an exposure apparatus 10 according to one embodiment of the present invention will be explained first with reference to FIG. 1.

The exposure apparatus 10 projects and transfers a pattern formed on an original (to be referred to as a mask hereinafter) M onto a substrate (to be referred to as a wafer hereinafter) P coated with a photosensitive material (to be referred to as a resist hereinafter). The exposure apparatus 10 includes, e.g., a light source 15, illumination optical system 14, original stage 13, projection optical system 12, substrate stage 11, and control unit 17.

The original stage (to be referred to as a mask stage hereinafter) 13 holds the mask M. Note that the mask M is arranged on the object plane of the projection optical system 12. The light source 15 emits a light beam L used for exposure of the wafer P. The light beam L emitted by the light source 15 is provided to the illumination optical system 14 upon being reflected by a reflecting mirror 16. The illumination optical system 14 irradiates the mask M with the light beam L from the light source 15. The light beam L emerging from the mask M upon this irradiation forms an image on the substrate, i.e., the wafer P via the projection optical system 12. A pattern image of the mask M is formed on the surface of the wafer P. The exposure apparatus 10 drives the substrate stage (to be referred to as a wafer stage hereinafter) 11 by a driving mechanism (not shown) to two-dimensionally move the wafer P step by step. In other words, the exposure apparatus 10 sequentially exposes each shot region on the wafer P while moving the wafer P step by step, thereby sequentially transferring the pattern of the mask M to each shot region on the wafer P. The control unit 17 systematically controls the above-mentioned process in the exposure apparatus 10. The processing function corresponding to the control unit 17 may be implemented by a computer provided outside the exposure apparatus 10.

The exposure apparatus 10 is also provided with an overlay measurement device 20. The overlay measurement device 20 may be provided outside the exposure apparatus 10 (an outboard type), or may be provided inside the overlay measurement device 20 (an inboard type). The overlay measurement device 20, for example, observes a mark image formed on the wafer P (to be often simply referred to as a mark image hereinafter) from directly above the surface of the wafer P by a scope, and outputs a measurement value using the measured waveform information obtained by the observation. Note that the expression “a mark formed on a wafer” includes “a mark formed on a resist” in the embodiments of the present invention.

### First Embodiment

The first embodiment will be explained herein. A case in which the aberration of a projection optical system 12 in an exposure apparatus 10 shown in FIG. 1 is corrected using the SPIN or ISI method will be explained in the first embodiment.

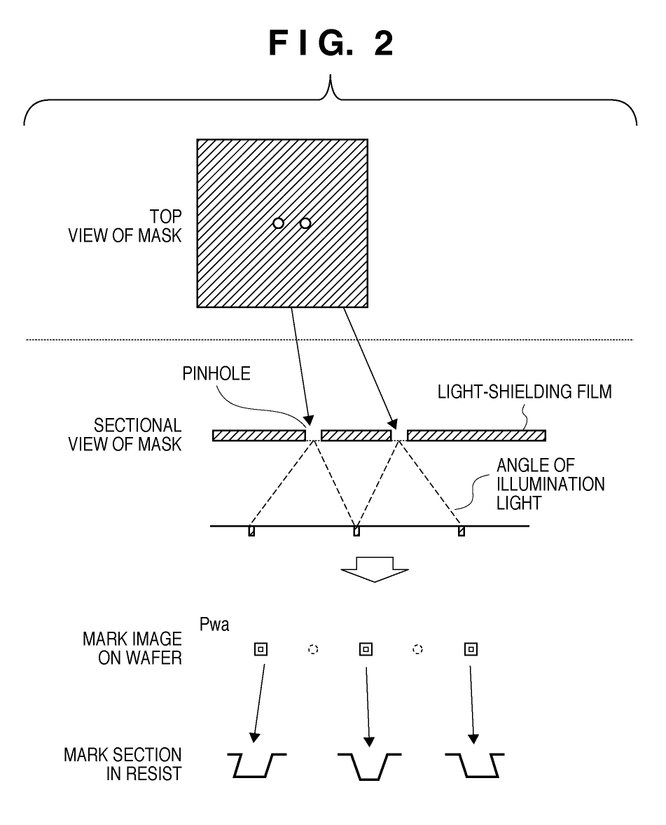

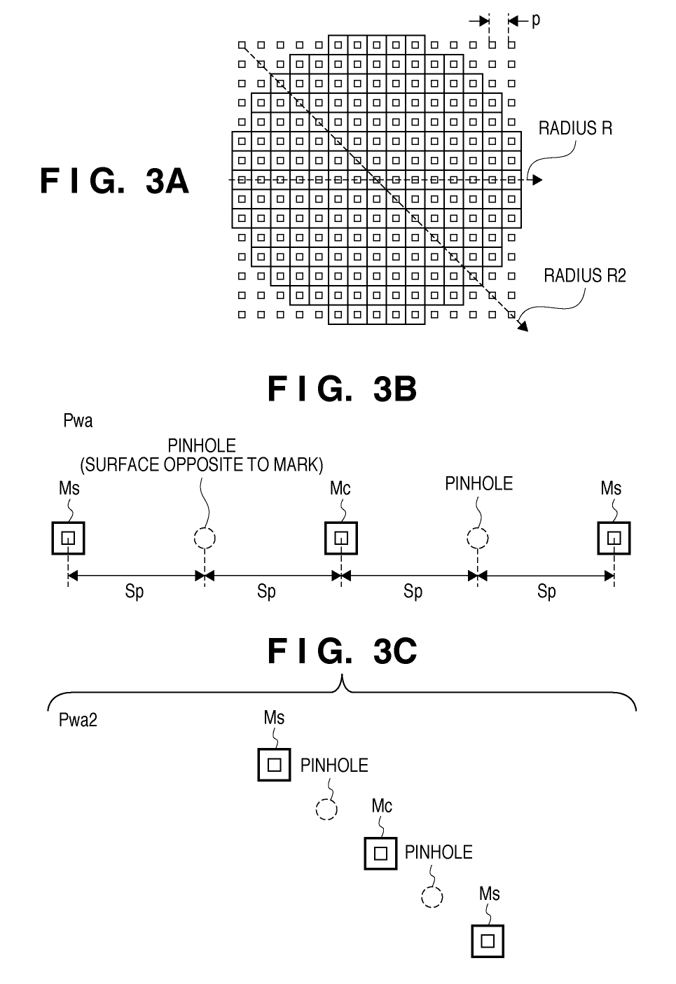

In this embodiment, the pattern of a calibration mark unit is provided on a mask, separately from a group of marks for measuring aberration, i.e., a unit of marks for measuring aberration, which is used for the conventional wavefront aberration measurement by the SPIN or ISI method. The calibration mark unit includes a mark for measuring a measurement error as a first mark, and a calibration mark for correction as a second mark. The calibration mark unit including these marks is transferred on a resist by oblique illumination via a pinhole on the mask, as shown in FIG. 2. The calibration mark unit is arranged to have a predetermined positional relationship with the pinhole in the horizontal direction, for example, in the R direction shown in FIG. 3A. Mark groups Pwa, shown in FIG. 3B, are provided at several mark positions in the R directions. More specifically, several arrangements which have different intervals Sp between the pinholes and the marks in the horizontal direction, i.e., several arrangements which form different oblique incident angles are provided. In this case, the interval Sp is desirably an integer multiple of a sampling pitch p shown in FIG. 3A. Mark groups Pwa having such arrangements are provided at several positions in the radial directions. For example, a mark group in the R2 direction has an arrangement as indicated by Pwa2 in FIG. 3C.

The exposure apparatus 10 transfers a calibration mark unit on the wafer, more specifically, on the resist while gradually driving the wafer along the optical-axis direction. Note that a position shift in a plane parallel to the wafer surface (substrate surface) is measured in a mark Ms, and a change of line width is measured in a mark Mc. An overlay measurement device 20, for example, need only be used in measuring a position shift and a change of line width.

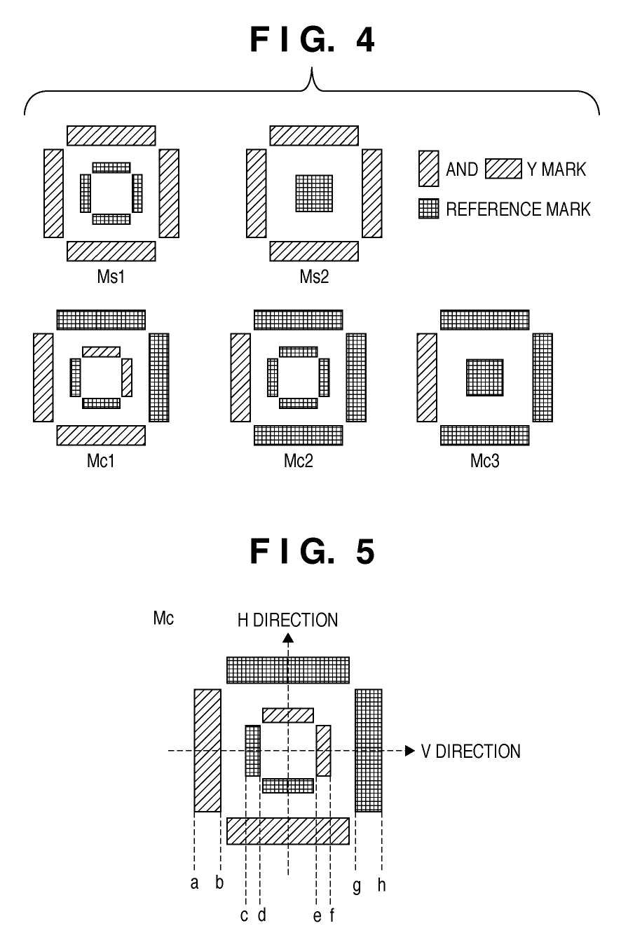

An example of the structures of the marks Ms and Mc will be explained with reference to FIG. 4.

The mark Ms includes a mark a position shift of which occurs in response to aberration (to be referred to as a Y mark hereinafter) as an outer mark. The Y mark is, for example, a special diffraction grating mark in the SPIN method. An inner mark of the mark Ms is a reference mark a position shift of which does not occur in response to aberration, and is formed from, for example, an isolated pattern having a line width of about several micrometers. The reference mark may be a rectangular box mark, as indicated by Ms2. Also, the mark Ms may have outer and inner marks of the types inverted with respect to those shown in FIG. 4.

The mark Mc includes, for example, Y marks as outer and inner marks each corresponding to one of opposite sides in each of the vertical and horizontal directions, and reference marks as outer and inner marks each corresponding to the other one of opposite sides, as indicated by Mc1. The mark Mc may include a Y mark as an outer or inner mark corresponding to one side, and reference marks as marks corresponding to the remaining sides, as indicated by Mc2. One or some of reference marks may be a rectangular box mark, as indicated by Mc3. The marks Mc2 and Mc3 may have inner and outer marks of the types inverted with respect to those shown in FIG. 4.

The patterns of Y marks and reference marks for forming marks Ms and Mc are arranged on different masks or at different positions on a single mask. The exposure apparatus 10 irradiates such a mask to transfer Y marks on it. After that, the exposure apparatus 10 drives a wafer stage 11 and transfers reference marks so as to be superimposed on the Y marks. With this operation, superimposed marks for overlay measurement, which include inner and outer marks as shown in FIG. 4, are formed on the wafer, more specifically, on the resist. The Y marks and reference marks may be transferred in reverse order. Y marks and reference marks in the mark Mc may be formed as a pattern of overlay measurement marks on the mask from the beginning.

When the exposure apparatus 10 transfers Y marks while gradually changing the focus by driving the wafer stage 11 along the optical-axis direction, images of the Y marks of the mark Ms are formed by oblique illumination (illumination with light having an angular distribution asymmetrical with respect to the optical-axis direction). For this reason, a position shift occurs in the Y mark. As a consequence, the Y mark has a section formed into an oblique shape, and a measured waveform having asymmetrical two ends is obtained upon measurement by the overlay measurement device 20. When the overlay measurement device 20 measures a mark obtained by superimposing the Y marks and the reference marks, a position shift of the superimposed mark is detected. Because the mark Mc receives light from two pinholes and therefore undergoes non-oblique illumination, a position shift of the mark Mc attributed to the focus does not occur, but a change of line width of the Y mark attributed to the focus occurs.

The Y mark may be a mark for measuring aberration used in, for example, the SPIN or ISI method. The Y mark of the mark Mc desirably has a high rate of change of line width attributed to the focus. In the SPIN method, the Y mark of the mark Mc is preferably a special diffraction grating mark as described above, but may be an isolated pattern.

A change of line width of the mark Mc is measured by paying attention to, for example, individual edges of the inner and outer regions on the formed mark as shown in FIG. 5. When the mark Mc shown in FIG. 5 is seen from the V direction, there exist edges a, b, c, d, e, f, g, and h. For example, attention is paid to the edges c, f, a, and h first. In this case, the edges c and f are measured as those of the inner region, and the edges a and h are measured as those of the outer region to obtain a position shift S1. Attention is paid to the edges d, e, b, and g next. In this case, the edges d and e are measured as those of the inner region, and the edges b and g are measured as those of the outer region to obtain a position shift S2. Note that a position shift between the centers of the inner and outer regions, for example, is measured assuming that the edges a, b, c, d, e, f, g, and h are the coordinates of respective edges. Then, the S1, S2, and S1-S2 are given by:

S1=(c+f)/2−(a+h)/2 (1)

S2=(d+e)/2−(b+g)/2 (2)

S1−S2=((b−a)+(f−e))/2+((c−d)+(g−h))/2 (3)

where ((b−a)+(f−e))/2 is the line width of the Y mark, and other terms are constants within a certain focus range.

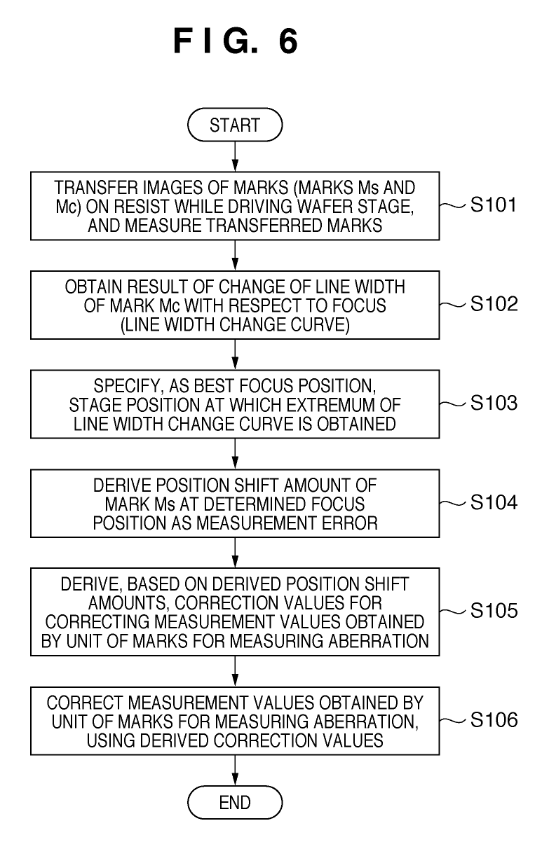

An example of a sequence of measuring the optical characteristic (a measurement error) of the projection optical system 12 in the exposure apparatus 10 will be explained herein with reference to FIG. 6.

First, a control unit 17 of the exposure apparatus 10 transfers onto a resist a pattern formed on a mask, i.e., images of marks Ms and Mc by irradiation with light from a light source while gradually driving the wafer stage (wafer) along the optical-axis direction. At this time, the overlay measurement device 20 measures a change of line width of the transferred mark Mc at each stage of driving the wafer along the optical-axis direction. The overlay measurement device 20 measures a position shift of the transferred mark Ms as well (step S101).

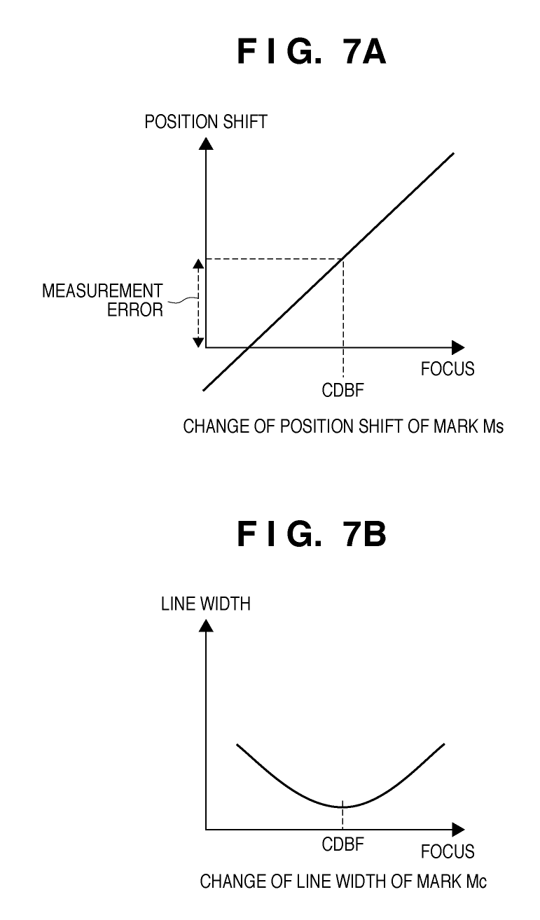

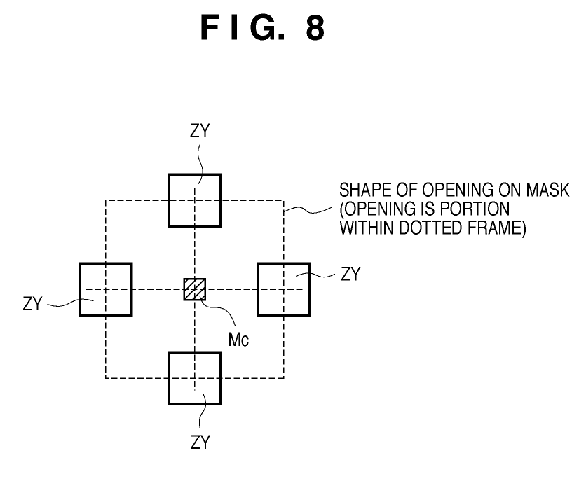

The control unit 17 of the exposure apparatus 10 acquires, from the overlay measurement device 20, the measurement value of the mark measured while gradually changing the focus to obtain the result of a change of line width with respect to the focus (line width change curve) using equation (3) (step S102). The obtained line width change curve is, for example, as shown in FIG. 7B.

After obtaining the line width change curve, the control unit 17 of the exposure apparatus 10 calculates an extremum of the line width change curve with respect to the focus, and specifies the focus position at which an extremum is obtained as a best focus position (the best focus position will be referred to as a CDBF hereinafter) (step S103).

The control unit 17 of the exposure apparatus 10 calculates CDBFs in several mark groups Pwa in both the V and H directions, and, at the same time, calculates the position shift amount of the mark Ms at the CDBF in each mark group Pwa (step S104). As a consequence, the position shift amount at the CDBF in each mark group Pwa in the V and H directions is derived, as shown in FIG. 7A. The position shift amount in each mark group Pwa is a measurement error at a position corresponding to the pupil coordinates of the mark group Pwa.

The control unit 17 of the exposure apparatus 10 arithmetically processes the position shift measurement value in a polar coordinate system using the pupil center as the origin to calculate a correction value at each point (step S105). The measurement value of a mark for measuring aberration used in wavefront aberration measurement is corrected using the correction value (step S106). The measurement value may be corrected using the result of converting the correction value into a Zernike coefficient.

### Second Embodiment

The second embodiment will be explained next. A case in which the aberration of a projection optical system 12 in an exposure apparatus 10 shown in FIG. 1 is corrected using the ZEX method will be explained in the second embodiment.

The ZEX method is a method of calculating each Zernike coefficient from the result of illuminating the patterns of several Y marks formed on the mask pattern surface via an opening which has a special shape and is formed on the surface, opposite to the mask pattern surface, of the mask and measuring relative position shifts of the mark images. A measurable Zernike term is determined depending on the shape of an opening formed on the surface, opposite to the mask pattern surface, of the mask. In addition, the oblique incident angle on a mark is determined depending on the relative position between the opening and the mark, the shape of the opening, and the illumination shape of an illumination optical system in an exposure apparatus.

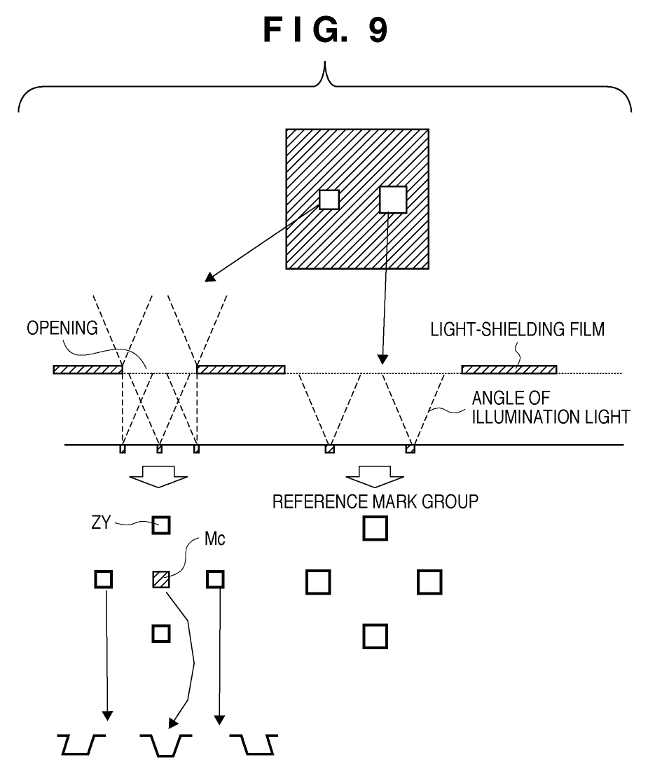

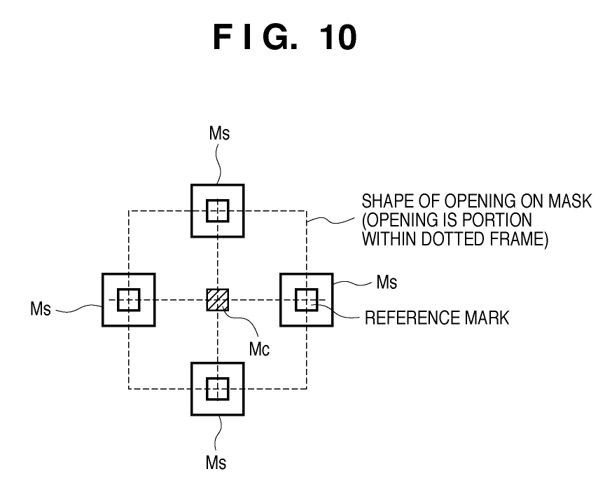

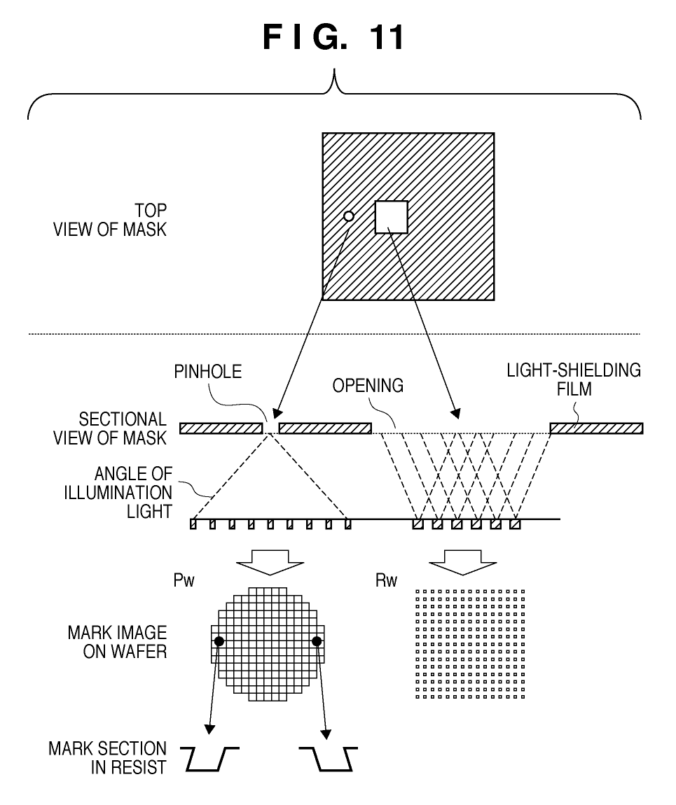

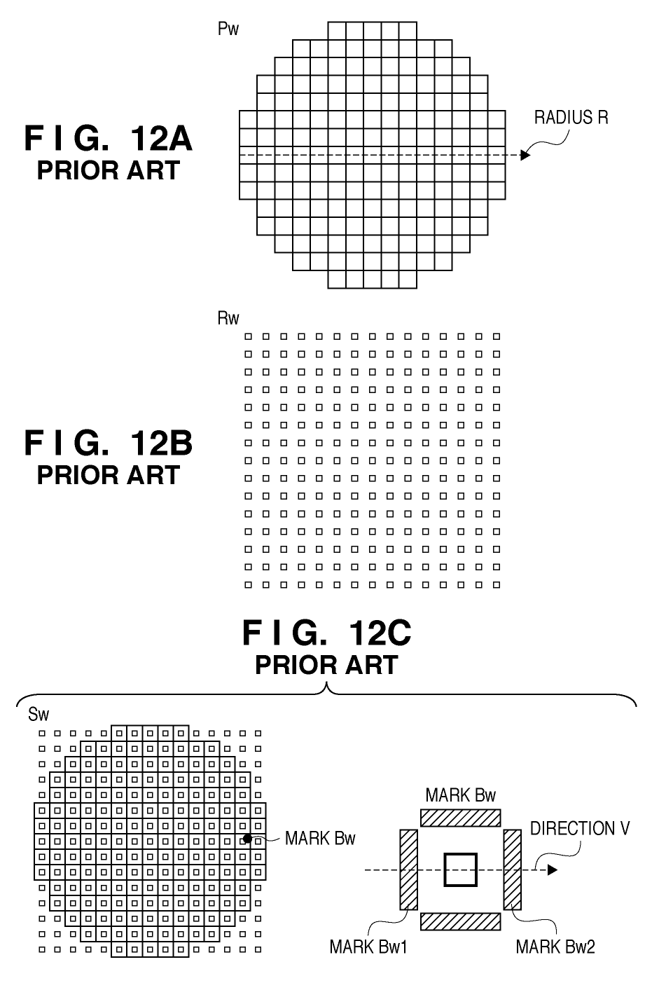

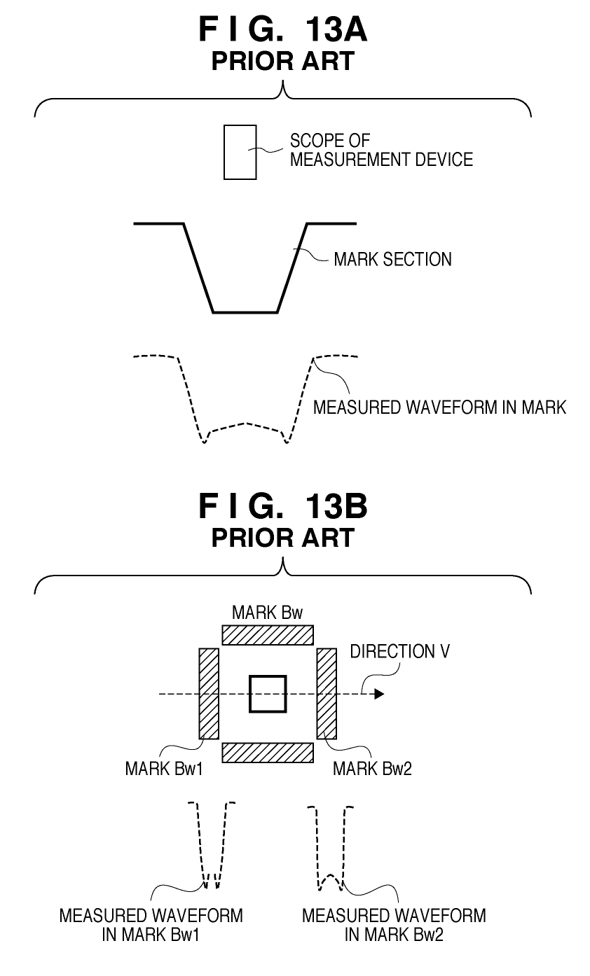

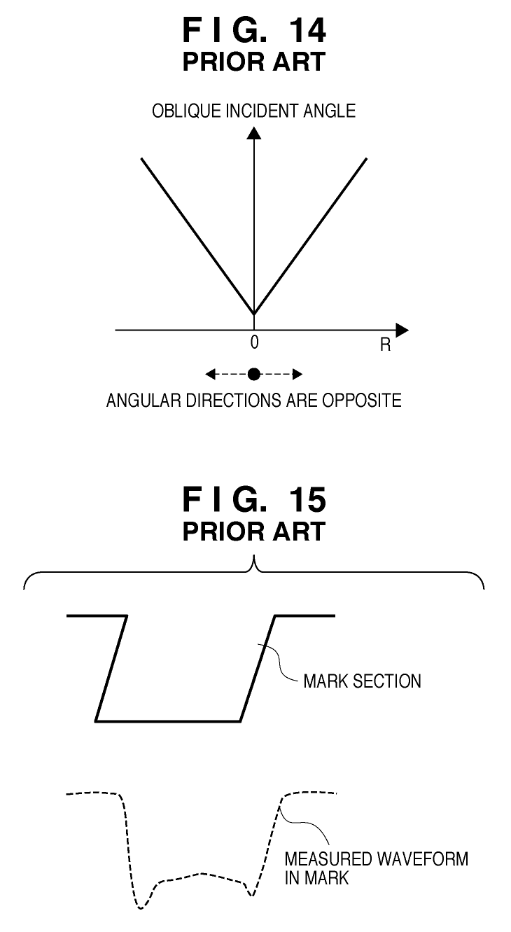

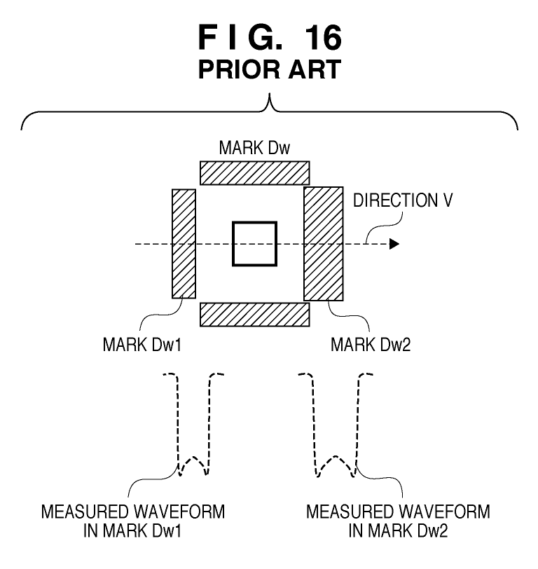

A method which uses an opening and mark arrangement for measuring a spherical aberration term (to be referred to as the Z-SPIN method hereinafter) will be exemplified as the ZEX method herein. In the Z-SPIN method, the positional relationship between the opening and marks in the horizontal direction is, for example, as shown in FIG. 8. The illumination shape becomes a semicircular shape or a half-ring shape by combining four (or two) marks ZY with the illumination condition of the exposure apparatus 10. The exposure apparatus 10 transfers each mark ZY on a wafer and transfers a reference mark so as to be superimposed on each mark ZY, as shown in FIG. 9. As a consequence, marks Ms as shown in FIG. 10 are formed, and position shifts of images of the formed marks Ms are measured. The measurement value in the Z-SPIN method is calculated from the values of the position shifts. The mark Mc is a calibration mark and is arranged at a position at which the mark Mc and the opening hold a relationship which allows the mark Mc to undergo non-oblique illumination. The mark Mc is desirably arranged near the marks Ms. For example, the mark Mc is preferably arranged at the center of the arrangement of the four marks Ms, as shown in FIG. 10.

The marks Ms and Mc have the same structures as in the first embodiment described above, and include Y marks and reference marks. The patterns of Y marks and reference marks for forming marks Ms and Mc are arranged on different masks or at different positions on a single mask. Y marks and reference marks in the mark Mc may be formed as a pattern of an overlay measurement mark on the mask from the beginning.

An overlay measurement device 20 measures a position shift of each mark Ms and measures a change of line width of the mark Mc in response to a change in the focus. An extremum of a change of line width of the mark Mc in response to a change in the focus is calculated, and the Z-SPIN measurement result is corrected using, as a correction value, the position shift measurement value of each mark Ms at the focus position (CDBF) at which an extremum is obtained, or the Z-SPIN method measurement value calculated from the position shift measurement value.

As described above, according to the first and second embodiments, it is possible to eliminate any errors attributed to the oblique incident angle, the type of resist, the resist film thickness, the type of measurement device, and the measurement algorithm, thus improving the absolute value precision of a measurement method. For example, since the aberration of a projection optical system in an exposure apparatus is measured by measuring the optical characteristic of the projection optical system and correcting the aberration measurement value in accordance with the measured optical characteristic, the measurement precision improves.

The magnitude of a measurement error changes depending on the oblique incident angle, the type of resist, the resist film thickness, the type of measurement device, and the measurement algorithm. For this reason, when the wavefront aberrations of a projection optical system in an exposure apparatus are measured by, e.g., the SPIN method using, e.g., different types of resists, different resist film thicknesses, different types of measurement devices, and different measurement algorithms in pre-shipment adjustment and post-shipment setting adjustment of the exposure apparatus, different measurement results are obtained before and after the shipment. This occurs because, owing to measurement errors, the result shows as if the wavefront aberration of the projection optical system had changed although it in fact has not changed. According to the embodiments described above, it is possible to solve this problem.

Also, according to the first and second embodiments, it is possible to cope with the problem that the difference in line width between marks worsen the measurement errors by correcting this difference. Note that since the measurement error can be managed as an offset for each oblique incident angle, each type of resist, each resist film thickness, each type of measurement device, and each measurement algorithm, once an offset is calculated under each condition, it can be repeatedly used for correction.

Although exemplary embodiments of the present invention have been explained above, the present invention is not limited to the embodiments which have been described above and are shown in the drawings, and can be practiced by appropriately modifying the embodiments without departing from the spirit and scope of the present invention.

For example, even in an arrangement as described in Japanese Patent Laid-Open No. 2002-55435, it is possible to eliminate any measurement errors by forming images of marks Mc as described above on a wafer, and performing correction based on the mark measurement results.

Although a case in which an overlay measurement device 20 is used for mark measurement has been explained in the first and second embodiments, the present invention is not limited to this, and mark measurement may be performed using an alignment scope mounted in an exposure apparatus.

Devices (e.g., a semiconductor integrated circuit and a liquid crystal display device) are manufactured by an exposure step of exposing a substrate (e.g., a wafer or a glass plate) coated with a photoresist (photosensitive agent) using the exposure apparatus 10 shown in FIG. 1 described above, a development step of developing the exposed substrate, and other known steps.

According to the present invention, it is possible to eliminate any errors attributed to, e.g., the oblique incident angle, the type of resist, the resist film thickness, the type of measurement device, and the measurement algorithm, thus improving the absolute value precision of a measurement method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-124968 filed on May 12, 2008, which is hereby incorporated by reference herein in its entirety.

What is claimed is:

1. An exposure apparatus comprising:
a projection optical system configured to project a pattern of an original onto a substrate; and
a control unit,
wherein said control unit
acquires a result of measuring a line width of an image of a first mark and a position of an image of a second mark, wherein the first mark and the second mark are formed on the substrate at each position while gradually changing a position of a substrate stage in an optical-axis direction, and
derives a position shift amount of the image of the second mark formed on the substrate held by the substrate stage at a position, in the optical-axis direction, at which an extremum of a change of line width of the image of the first mark is measured.

2. The apparatus according to claim 1, wherein said control unit corrects aberration of said projection optical system by correcting, using the derived position shift amount, a measurement result of an image of a mark for measuring aberration.

3. The apparatus according to claim 1, wherein said control unit controls a process for projecting a pattern of an original on which a pattern including the first mark and the second mark is formed onto the substrate via said projection optical system.

4. The apparatus according to claim 1, wherein the position shift amount is included in a measurement error which occurs when an image of a mark for measuring aberration, which is formed on the substrate using light having an angular distribution asymmetrical with respect to the optical-axis direction, is measured.

5. A correction method of correcting aberration of a projection optical system in accordance with a measurement result of an image of a mark for measuring aberration, the method comprising:
measuring a line width of an image of a first mark and a position of an image of a second mark, wherein the first mark and the second mark are formed on a substrate at each position while gradually changing a position of a substrate stage in an optical-axis direction;
deriving a position shift amount of the image of the second mark formed on the substrate held by the substrate stage at a position, in the optical-axis direction, at which an extremum of a change of line width of the image of the first mark is measured; and
correcting aberration of the projection optical system by correcting, using the derived position shift amount, the measurement result of the image of the mark for measuring aberration.

6. A device manufacturing method comprising:
exposing a substrate by an exposure apparatus; and
developing the substrate,
wherein the exposure apparatus includes
a projection optical system configured to project a pattern of an original onto a substrate, and
a control unit, and
the control unit
acquires a result of measuring a line width of an image of a first mark and a position of an image of a second mark, wherein the first mark and the second mark are formed on the substrate at each position while gradually changing a position of a substrate stage in an optical-axis direction, and
derives a position shift amount of the image of the second mark formed on the substrate held by the substrate stage at a position, in the optical-axis direction, at which an extremum of a change of line width of the image of the first mark is measured.
